(19) United States
(12) Patent Application Publication
(10) Pub. No.: US 2003/0057521 A1
(43) Pub. Date: Mar. 27, 2003

(54) Semiconductor structure used for fabricating bipolar transistors and method of fabricating the same

(75) Inventor: Fumihiko Hirose, Kanagawa-ken (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: MITSUBISHI HEAVY INDUSTRIES, LTD., TOKYO (JP)

(21) Appl. No.: 10/247,687

(22) Filed: Sep. 20, 2002

(30) Foreign Application Priority Data
Sep. 21, 2001 (JP) 2001-288635
Nov. 19, 2001 (JP) 2001-353296

(51) Int. Cl. H01L 29/00

(52) U.S. Cl. 257/565; 257/555

(57) ABSTRACT

A semiconductor structure used for fabricating bipolar transistors. A semiconductor structure is composed of a substrate, and a layered semiconductor structure. The layered semiconductor structure consists of a first layer covering the substrate, a second layer covering the first layer, and a third layer covering the second layer. The first layer includes a first semiconductor layer of a first conductivity type. The second layer includes a second semiconductor layer of a second conductivity type. The third layer includes a third semiconductor layer of the first conductivity type.

### BACKGROUND OF THE INVENTION

1. Field of the Invention

The present invention relates, in general, to a semiconductor structure and a method of manufacturing the same and, more particularly, to a semiconductor structure that facilitates manufacture of silicon-germanium bipolar transistors that have a desired performance.

2. Description of the Related Art

Bipolar transistors have been widely used as electronic switches. A bipolar transistor usually includes three semiconductor layers: a first semiconductor layer of a first conductivity type, a second semiconductor layer of a second conductivity type formed on the first semiconductor layer, and a third semiconductor layer of the first conductivity type. The three semiconductor layers respectively acts as a collector, a base, and an emitter.

Bipolar transistors often adopt a more complicated structure in order to increase the breakdown voltage and output power thereof. FIG. 1 shows an NPN⁻N⁺ bipolar transistor. A heavily doped N+ semiconductor substrate 101 is covered with a lightly doped N-type semiconductor layer 102. A P-type semiconductor layer 103 and a semiconductor layer 104 are laminated in series on the N-type semiconductor layer 102. The semiconductor layers 102 through 104 are typically formed from silicon. The N+ semiconductor substrate 101 and the N-type layer 102 act as a collector. Portions 104a of the semiconductor layer 104 have P-type dopants, while the remaining portions are doped with N-type dopants. The P-type semiconductor layer 103 and the P-type portions 104a act as a base, and the remaining N-type portions of the semiconductor layer 104 acts as an emitter. Base electrodes 105 are respectively formed on the P-type portions 104a, and emitter electrodes 106 are respectively formed on the N-type portions of the semiconductor layer 104. The rear surface of the N+ semiconductor substrate 101 is covered with a metal layer, which acts as a collector electrode 107.

FIG. 2 shows a switching circuit including a bipolar transistor. An emitter 109 of a bipolar transistor 108 is connected to a collector 110 of the bipolar transistor 108 through a load 111 and a power supply 112. The bipolar transistor 108 is turned on and off in response to the base current Ib. When the base current Ib is zero, the impedance between the emitter 109 and the collector 110 is extremely large, that is, the bipolar transistor 108 is turned off. When the base current Ib is larger than a threshold, on the other hand, the impedance between the emitter 109 and the collector 110 is small, that is, the bipolar transistor 108 is turned on.

The performance of a bipolar transistor include a breakdown voltage, a maximum collector current, a switching time, a turn-on voltage, and a forward current gain. The breakdown voltage is the maximum voltage allowed to be applied to the transistor. A high breakdown voltage allows the bipolar transistor to operate on a high power supply voltage, and thus improves the applicability of the bipolar transistor. The maximum collector current depends on the size of the bipolar transistor. The increase of the maximum collector current can be achieved by enlarging the size of the bipolar transistor. It is advantageous for a bipolar transistor to have a short switching time. A short switching time suppresses the heat generation, which implies that the switching loss is small. In addition, a short switching time increases the operation frequency of the bipolar transistor, and this increases the applicability of the bipolar transistor. It is of further advantage for a bipolar transistor to have a low turn-on voltage. A low turn-on voltage reduces heat generated by the bipolar transistor. In addition, a large forward current gain is quite preferable in terms of the performance of a bipolar transistor. A large forward current gain reduces a power consumption of a circuit for driving a transistor.

The improvement of the performance of bipolar transistors has been desired. The performance of bipolar transistors strongly depends on the structure thereof and the physical properties of semiconductor layers. For example, film thicknesses and impurity concentrations of an emitter, a base, and a collector have an influence on the performance of bipolar transistors. In order to improve the performance of bipolar transistors, optimization of the structure and the fabrication process is of importance. FIGS. 3A to 3D, and 4A to 4C show a typical process of manufacturing an NPN bipolar transistor. With reference to FIG. 3A, a semiconductor structure 123 is provided which includes a silicon substrate 122 and a lightly doped N-type epitaxial film 121 formed on the silicon substrate 122. A collector layer is formed in the n-type epitaxial film 121. In many cases, the semiconductor structure 123 is manufactured by a substrate manufacturer, and the transistor manufacturer purchases the semiconductor structure 123 to manufacture bipolar transistors. As shown in FIG. 3B, a P-type epitaxial film 124 and an N-type epitaxial film 125 are deposited in series on the N-type epitaxial film 121 by using a chemical vapor deposition (CVD) method. The P-type epitaxial film 124 acts as a base, and the N-type epitaxial film 125 acts as en emitter.

As shown in FIG. 3C, silicon oxide films 126 are then formed on the N-type epitaxial film 125. The silicon oxide films 126 are used as diffusion masks. Then, as shown in FIG. 3D, P-type dopants are diffused into portions of the N-type epitaxial film 125. The conductivity type of the diffused portions is inverted to form P-type regions. After the removal of the silicon oxide films 126, metal electrodes 127 and 128 are formed as shown in FIG. 4A. After a transistor mesa is formed by an etching, as shown in FIG. 4B, a collector electrode is formed on the rear surface of the silicon substrate 122. As shown in FIG. 4C, the silicon substrate 122 is then diced into discrete transistors. The diced transistors are then sealed with a metallic box or resin to complete the transistor product.

The formation of the base layer and the emitter layer is one of the most important processes to improve the performance of bipolar transistors. For example, a thin base layer increases the operation speed, and exclusion of the defects in the base layer and the emitter layer improves the breakdown voltage.

The importance of the formation of the base and emitter layers encourages manufacturers of bipolar transistors to optimize CVD processes. However, the optimization of CVD processes imposes a large cost for the manufacturers. For instance, the manufacturers have to be equipped with CVD apparatuses. It would be advantageous to facilitate the establishment of the CVD processes for fabricating bipolar transistors. It would be also advantageous if the manufacturers are free from the optimization of CVD processes for improving the performance of bipolar transistors.

### SUMMARY OF THE INVENTION

Therefor, an object of the present invention is to provide a semiconductor structure that facilitates the establishment of the manufacture process of bipolar transistors tat have a desired performance.

Another object of the present invention is to provide a semiconductor structure that enables manufacturers to fabricate bipolar transistors that have a desired performance without CVD apparatuses.

In an aspect of the present invention, a semiconductor structure used for fabricating bipolar transistors is composed of a substrate, and a layered semiconductor structure. The layered semiconductor structure consists of a first layer covering the substrate, a second layer covering the first layer, and a third layer covering the second layer. The first layer includes a first semiconductor layer of a first conductivity type. The second layer includes a second semiconductor layer of a second conductivity type. The third layer includes a third semiconductor layer of the first conductivity type.

The above-mentioned “consist of” implies that the third layer is covered with nothing.

It is desirable that the first semiconductor layer mainly consists of silicon, and the second semiconductor layer mainly consists of silicon and germanium, and the third semiconductor layer mainly consists of silicon.

The second semiconductor layer preferably has a germanium concentration of more than 2.5 atomic percent.

The second semiconductor layer preferably includes a silicon layer and a silicon-germanium layer.

The second semiconductor layer preferably has a thickness of less than 1.0 micrometer.

Defect densities in the first through third semiconductor layers are preferably less than 5000 cm⁻².

Average roughnesses of the first through third semiconductor layers are preferably less than 10 Å.

In another aspect of the present invention, a method of fabricating a semiconductor structure used for manufacturing bipolar transistors, the method being composed of:

depositing a first layer on a substrate, the first layer including a first semiconductor layer of a first conductivity type,

depositing a second layer on the first layer, the second layer including a second semiconductor layer of a second conductivity type,

depositing a third layer on the second layer, the third layer including a third semiconductor layer of the first conductivity type,

packing the substrate into a box with the third layer covered with nothing; and

sealing the box.

In still another aspect of the present invention, a method of fabricating and selling a transistor is composed of:

purchasing a semiconductor structure;

manufacturing a bipolar transistor in the semiconductor structure,

shipping the bipolar transistor, the semiconductor structure consisting of:

a first layer covering the substrate, the first layer comprising a first semiconductor layer of a first conductivity type,

a second layer covering the first layer, the second layer comprising a second semiconductor layer of a second conductivity type, and

a third layer covering the second layer, the third layer comprising a third semiconductor layer of the first conductivity type.

In still another aspect of the present invention, a method of fabricating a switching circuit is composed of:

purchasing a semiconductor structure,

manufacturing a bipolar transistor on the semiconductor structure, and

assembling the bipolar transistor into a switching circuit, wherein the semiconductor structure consists of:

a first layer covering the substrate, the first layer comprising a first semiconductor layer of a first conductivity type,

a second layer covering the first layer, the second layer comprising a second semiconductor layer of a second conductivity type, and

a third layer covering the second layer, the third layer comprising a third semiconductor layer of the first conductivity type.

### BRIEF DESCRIPTION OF THE DRAWINGS

FIG. 1 shows a typical NPN⁻N⁺ bipolar transistor;

FIG. 2 shows a switch circuit including a bipolar transistor;

FIGS. 3A to 3D are sectional views showing a conventional process for fabricating a bipolar transistor; and

FIGS. 4A to 4C are sectional views showing the conventional process for fabricating the bipolar transistor;

FIG. 5 is a section view showing a first embodiment of a semiconductor structure according to the present invention;

FIGS. 6 to FIG. 12 are section views showing a method of manufacturing bipolar transistors in the first embodiment;

FIG. 13 is a table showing a performance of the bipolar transistor in the first embodiment;

FIG. 14 is a section view showing a second embodiment of a semiconductor structure according to the present invention; and

FIG. 15 is a table showing a performance of bipolar transistors in the second embodiment.

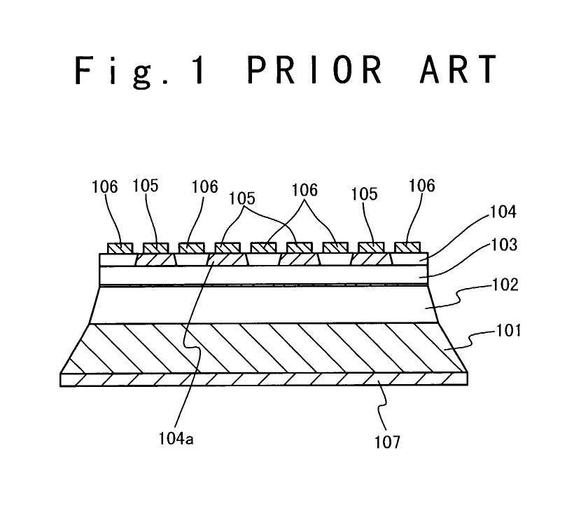

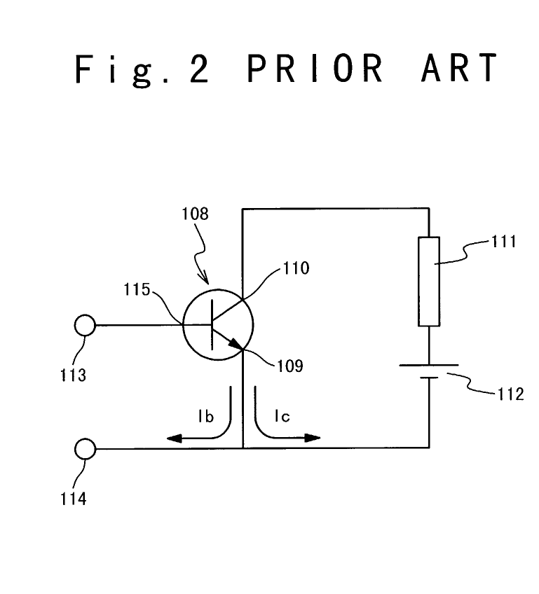

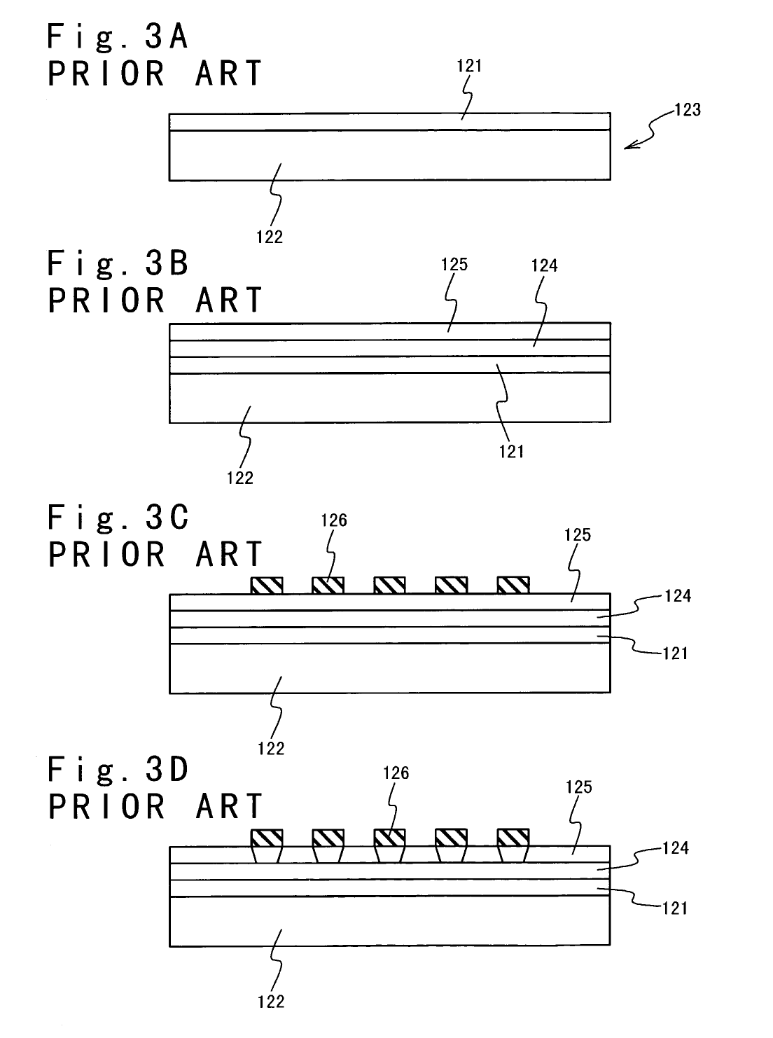

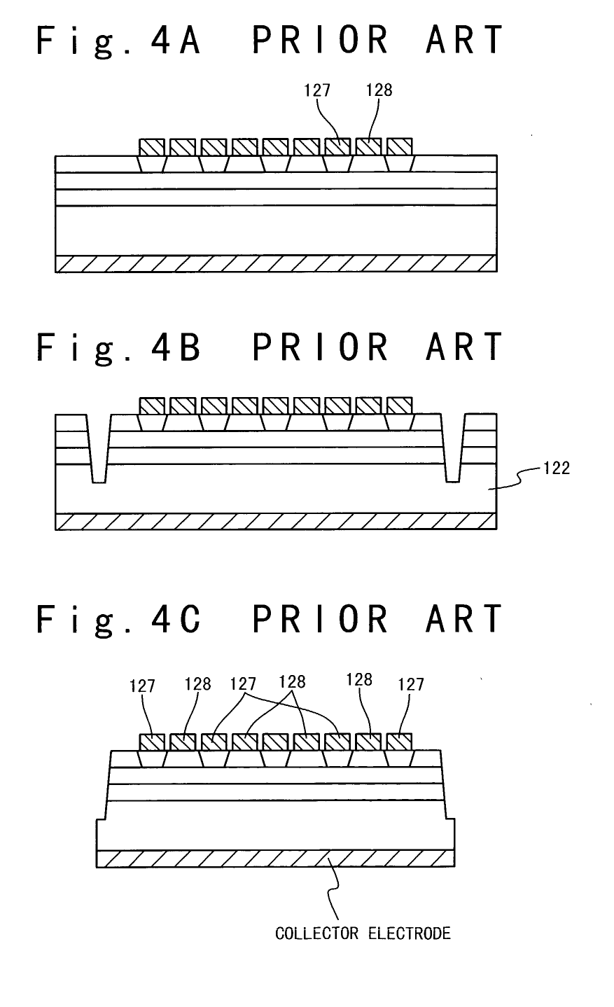

### DESCRIPTION OF THE PREFERRED EMBODIMENTS

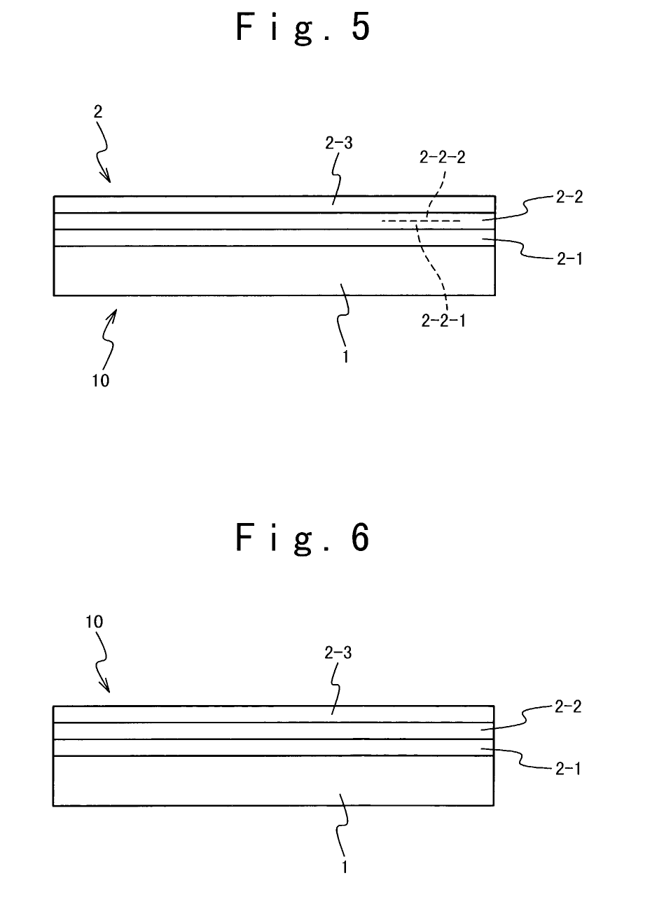

In an embodiment of a semiconductor structure according to the present invention, a silicon substrate 1 is provided with a layered semiconductor structure 2, as shown in FIG. 5. The layered semiconductor structure 2 is composed of a first semiconductor layer 2-1, a second semiconductor layer 2-2, and a third semiconductor layer 2-3. The first semiconductor layer 2-1 is formed on or over the silicon substrate 1. The second semiconductor layer 2-2 is formed on or over the first semiconductor layer 2-1. The third semiconductor layer 2-3 is formed on or over the second semiconductor layer 2-2. The first semiconductor layer 2-1 acts as a collector, the second semiconductor layer 2-2 acts as a base, and the third semiconductor layer 2-3 acts as an emitter.

When the semiconductor structure 10 is provided for manufacturing NPN transistors, the first semiconductor layer 2-1 is an N-type silicon layer, the second semiconductor layer 2-2 is an P-type silicon-germanium layer, and the third semiconductor layer 2-3 is an N-type silicon layer.

The second semiconductor layer 2-2 contains germanium. It is definitively important that the germanium concentration therein is higher than 2.5 atomic percent to improve the performance of the bipolar transistor. The high germanium concentration of the second semiconductor layer 2-2 increases the mobility in the vicinity of the boundary between the first semiconductor layer 21 (which acts as the collector) and the second semiconductor layer 2-2 (which acts as the base). The increase of the mobility leads to an increase in the operation speed of the bipolar transistor. The germanium concentration higher than 2.5 atomic percent also increases the injection efficiency of carriers from the third semiconductor layer 2-3 (which acts as the emitter) into the second semiconductor layer 2-2, and thus increases the forward current gain. The germanium concentration higher than 2.5 atomic percent is one of the conditions necessary to increase the operation speed and the forward current gain. It has been experimentally confirmed that the increases in the operation speed and the forward current gain requires the germanium concentration higher than 2.5 atomic percent.

The second semiconductor layer 2-2 preferably includes a silicon layer 2-2-1 formed on the first semiconductor layer 2-1, and a silicon-germanium layer 2-2-2 formed on the silicon layer 2-2-1. The layered structure of the second semiconductor layer 2-2 increases the transport efficiency of carriers from the emitter to the collector, and thus increases the forward current gain. When the second semiconductor layer 2-2 is composed of the silicon layer 2-2-1 and the silicon-germanium layer 2-2-2, the increases in the operation speed and the forward current gain is achieved by that the germanium concentration of the silicon-germanium layer 2-2-2 is higher than 2.5 atomic percent. This has been experimentally confirmed.

It is of further importance that a thickness of the second semiconductor layer 2-2 is equal to or less than 1.0 μm. The importance of the thin thickness of the second semiconductor layer 2-2 has been experimentally confirmed. The thin thickness of the second semiconductor layer 2-2 is important from the viewpoint of the increases of the operation speed and the forward current gain.

It is also important that the respective defect densities of the first semiconductor layer 2-1, the second semiconductor layer 2-2 and the third semiconductor layer 2-3 are equal to or less than 5000 cm⁻², and respective average roughnesses of the first semiconductor layer 2-1, the second semiconductor layer 2-2 and the third semiconductor layer 2-3 are equal to or less than 10 Å. The reduced defect densities and average roughnesses are ones of the essential conditions to improve the breakdown voltage of the bipolar transistor. It has been experimentally confirmed that the improvement of the breakdown voltage requires the reductions of the defect densities and the average roughnesses.

The fabrication of the semiconductor structure 10 is achieved by using a CVD method. The semiconductor layers 2-1 through 2-3 are deposited in series to cover the silicon substrate 1. The fabricated semiconductor structure 10 is provided for a manufacturer of bipolar transistors, and used for fabricating bipolar transistors. Before being shipped to the manufacturer of bipolar transistors, the semiconductor structure 10 is packed into a box and the box is completely sealed to protect the semiconductor structure 10 from contamination.

### First Embodiment

The semiconductor structure 10 is provided for a manufacturer of bipolar transistors. The silicon substrate 1 comprises single crystal silicon of a (100) crystallographic orientation, and has a diameter of 6 inches. The first semiconductor layer 2-1 has a thickness of 20 μm. The second semiconductor layer 2-2 is formed to have a thickness of 0.4 μm. The third semiconductor layer 2-3 is formed to have a thickness of 0.6 μm. The first semiconductor layer 2-1 is doped with P-type impurities and has an impurity concentration of 10¹⁴/cm³. The second semiconductor layer 2-2 is doped with P-type impurities and has an impurity concentration of 2×10¹⁷/cm³. The third semiconductor layer 2-3 is doped with N-type impurities, and has an impurity concentration of 5×10¹⁹/cm³. The germanium concentration of the second semiconductor layer 2-2 is 5 atomic percent. The average roughness of the semiconductor structure 10 is 5 Å, and the defect density thereof is less than 1000/cm². The defect density of the semiconductor structure 10 is determined by using microscope observation.

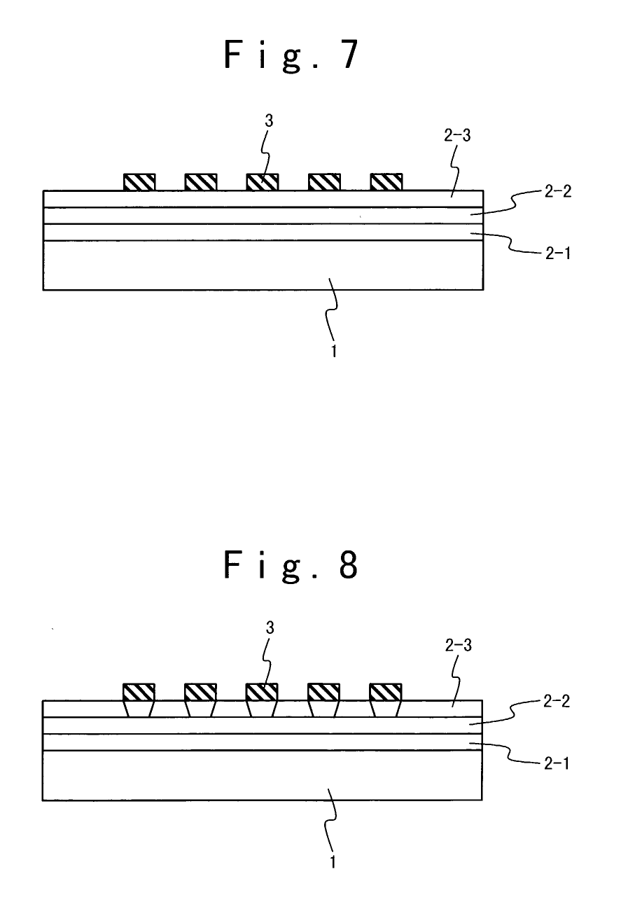

FIGS. 6 to 11 show a process for manufacturing bipolar transistors by using the semiconductor structure 10. As shown in FIG. 6, the semiconductor structure 10 is provided for a manufacturer of bipolar transistors. The manufacture purchases the semiconductor structure 10. As shown in FIG. 7, silicon oxide films 3 are then formed on the third semiconductor layer 2-3. As shown in FIG. 8, portions of the third semiconductor layer 2-3 are then counter-doped with the silicon oxide films 3 used as masks. The partial counter-doping forms P-type regions and N-type regions in the third semiconductor layer 2-3.

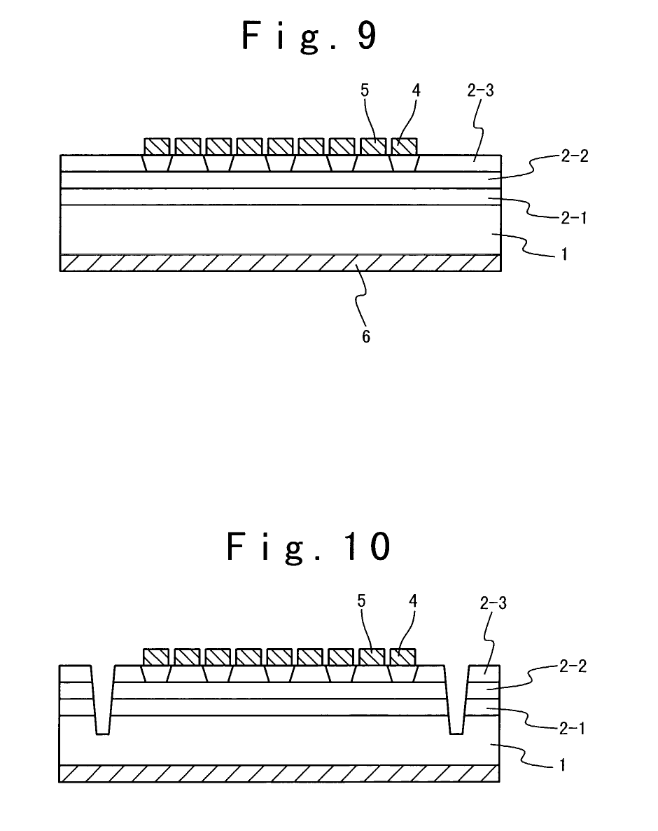

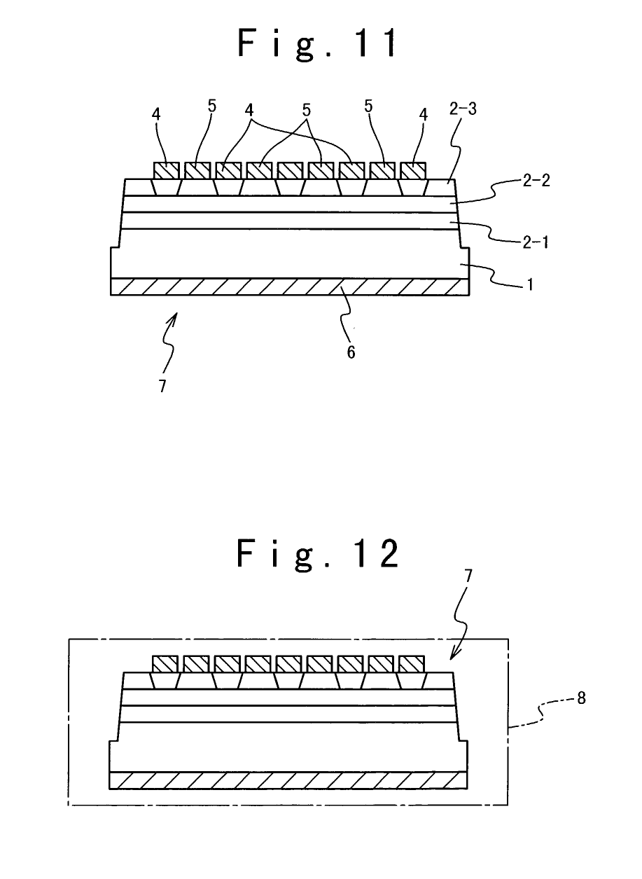

After the removal of the silicon oxide films 3, as shown in FIG. 9, emitter electrodes 4 are formed on the N-type regions of the third semiconductor layer 2-3, and base electrodes 5 are formed on the P-type regions. A collector electrode 6 is then formed on the rear surface of the silicon substrate 1. After the formation of the collector electrode 6, as shown in FIG. 10, portions of the third semiconductor layer 2-3, the second semiconductor layer 2-2, the first semiconductor layer 2-1, and the silicon substrate 1 are etched to form mesas. As shown in FIG. 11, the silicon substrate 1 is then diced to form discrete bipolar transistors 7. The size of the bipolar transistors 7 is 5 mm². As shown in FIG. 12, each of the bipolar transistors 7 is packed into a package 8 made from metal or resin. The bipolar transistors 7 are then shipped to customers. In order to provide switching circuits, the bipolar transistors 7 are assembled into the switch circuits.

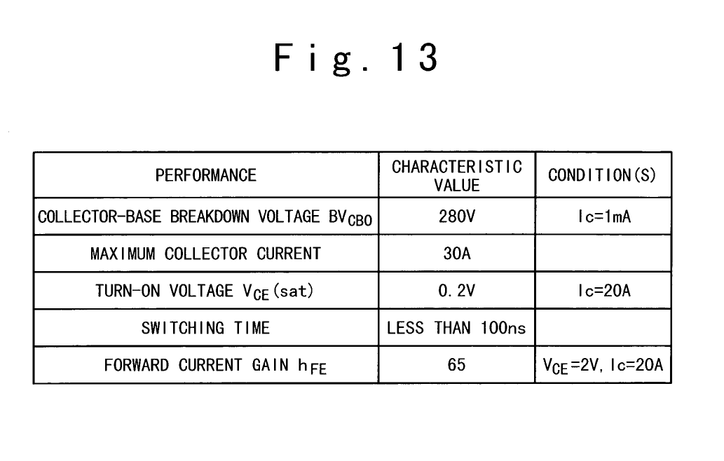

Using the semiconductor structure 10 enables manufacturers of bipolar transistors to easily fabricate bipolar transistors of a desired performance without any special apparatuses such as CVD apparatuses. It is advantageous for the transistor manufacturers because they are free from laborious optimization of the fabrication process. As shown in FIG. 13, it has been experimentally proved that the bipolar transistor 7 fabricated by the above-mentioned process shows a satisfactory performance.

### Second Embodiment

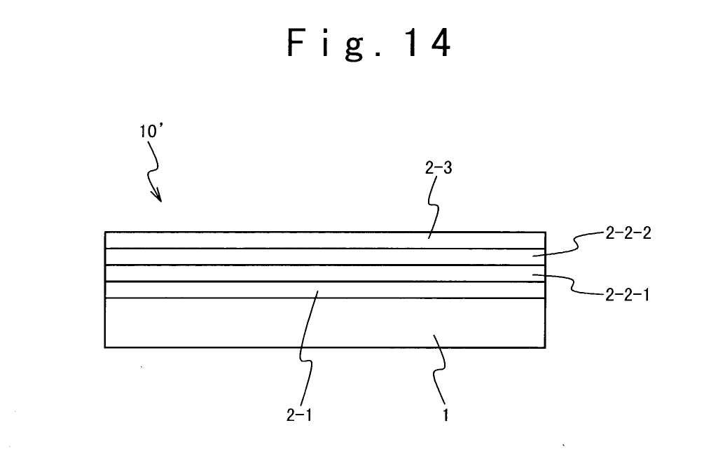

As shown in FIG. 14, a semiconductor structure 10′ is provided for a manufacturer of bipolar transistors. A second semiconductor layer 2-2 is composed of two layers: a P-type silicon-germanium layer 2-2-1, and a P-type silicon layer 2-2-2. The P-type silicon layer 2-2-2 is formed on the P-type silicon-germanium layer 2-2-1. The P-type silicon-germanium layer 2-2-1 and the P-type silicon layer 2-2-2 are formed to have a thickness of 0.2 μm. Impurity concentrations of the P-type silicon-germanium layer 2-2-1 and the P-type silicon layer 2-2-2 are 2×10¹⁷/cm³. The other conditions are equal to those of the above-mentioned transistor substrate 10.

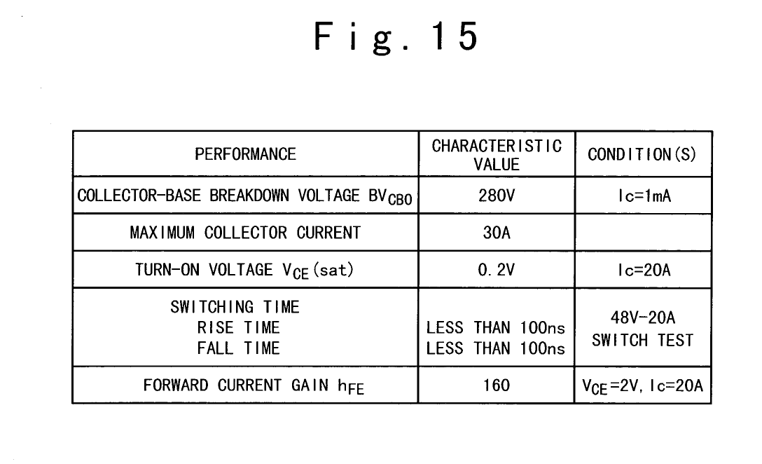

As shown in FIG. 15, it has been experimentally proved that bipolar transistors fabricated in the semiconductor structure 10′ show a satisfactory performance. A larger forward current gain factor is obtained in the second embodiment than in the first embodiment. The other performance of bipolar transistors in the second embodiment is substantially identical to that in the first embodiment.

### First Comparative Experiment

In a comparative experiment, a silicon layer is used as the base region. The bipolar transistor is manufactured by the above-mentioned process. A bipolar transistor fabricated in the first comparative experiment has a degraded switching time. The rising and falling times are on the order of several hundred nanoseconds. The operation speed is extremely degraded as compared with the first and second embodiments. The effectiveness of the use of the silicon-germanium layer is evidently proved.

A preferable range of the germanium concentration of the second semiconductor layer 2-2 (or the silicon-germanium layer 2-2-2) has been investigated. A plurality of semiconductor structures 10 that respectively have different germanium concentrations in the silicon-germanium layer has been fabricated. The respective germanium concentrations are 0.0, 2.5, 3.0, 4.0, 5.0, and 8.0 atomic percent. When the germanium concentration is 0.0 or 2.5 atomic percent, both of the rising time and the trailing time in the switching time are on the order of several hundred nanoseconds. The germanium concentration equal to or less than 2.5 atomic percent shows no effect on the performance of the bipolar transistors. When the germanium concentration is 3.0 atomic percent or more, both of the rising time and the trailing time in the switching time are 100 nanoseconds or less. The germanium concentration more than 2.5 atomic percent evidently improves the switching time, and thus increases the operation speed.

### Second Comparative Experiment

The thickness of the second semiconductor layer 2-2 (which acts as the base layer) has been investigated. When the thickness of the second semiconductor layer 2-2 is greater than 1.0 μm, rising and falling times of several hundred nanoseconds have been obtained. The operation speed is degraded if the second semiconductor layer 2-2 is thicker than 1.0 μm.

### Third Comparative Experiment

The average roughness of the semiconductor structure 10 has been investigated. When the average roughness ranges from 10 to 50 Å, the breakdown voltages of the bipolar transistors are null or less than 100 volts. Such a large roughness extremely degrades the breakdown voltage of bipolar transistors. It has been proved that the average roughness of the semiconductor structure 10 should be reduced to less than 10 Å.

### Fourth Comparative Experiment

The defect density of the semiconductor structure 10 has been investigated. When the defect density is 5000 to 10000/cm², the bipolar transistors have an average breakdown voltage of about 100 volts, which is much less than the breakdown voltage of 280 volts in the first embodiment. It has been proved that the defect density of the semiconductor structure 10 should be less than 5000/cm².

Although the invention has been described in its preferred form with a certain degree of particularity, it is understood that the present disclosure of the preferred form has been changed in the details of construction and the combination and arrangement of parts may be resorted to without departing from the spirit and the scope of the invention as hereinafter claimed.

In particular, the silicon substrate 1, the first semiconductor layer 2-1, the second semiconductor layer 2-2, and the third semiconductor layer 2-3 may be composed of a plurality of semiconductor layers, respectively. The first semiconductor layer 2-1 is composed of a silicon layer of a first conductivity type, and the second semiconductor layer 2-2 is composed of a silicon-germanium layer of a second conductivity type. The third semiconductor layer 2-3 is composed of a silicon layer of the first conductivity type. In the first embodiment, the third semiconductor layer 2-3 consists of a single N-type silicon layer. The third semiconductor layer 2-3 may includes a coating or a passivation layer as long as the performance required for the manufactured transistors is satisfied. However, the third semiconductor layer 2-3 substantially consists of the N-type single silicon layer. Manufacturers of bipolar transistors who purchase the semiconductor structure 10 can manufacture transistors having a desired performance without any modification in the layered-structure of the semiconductor structure 10.

### Advantageous Effects of the Invention

The semiconductor structure according to the present invention and the method of fabricating the same facilitate the establishment of the fabrication process of bipolar transistors of a desired performance. In particular, the semiconductor structure and the method of fabricating the same enable manufacturers to fabricate bipolar transistors having a desired performance without CVD apparatuses.

What is claimed is:

1. A semiconductor structure used for fabricating bipolar transistors, comprising:
a substrate; and
a layered semiconductor structure consisting of:
a first layer covering said substrate, said first layer comprising a first semiconductor layer of a first conductivity type,
a second layer covering said first layer, said second layer comprising a second semiconductor layer of a second conductivity type, and
a third layer covering said second layer, said third layer comprising a third semiconductor layer of said first conductivity type.

2. The semiconductor structure according to claim 1, wherein said third layer is covered with nothing.

3. The semiconductor structure according to claim 1, wherein said first semiconductor layer mainly consists of silicon, and
wherein said second semiconductor layer mainly consists of silicon and germanium, and
wherein said third semiconductor layer mainly consists of silicon.

4. The semiconductor structure according to claim 3, wherein said second semiconductor layer has a germanium concentration of more than 2.5 atomic percent.

5. The semiconductor structure according to claim 3, wherein said second semiconductor layer includes a silicon layer and a silicon-germanium layer.

6. The semiconductor structure according to claim 3, wherein said second semiconductor layer has a thickness of less than 1.0 micrometer.

7. The semiconductor structure according to claim 3, wherein defect densities in said first through third semiconductor layers are less than 5000 cm ⁻².

8. The semiconductor structure according to claim 7, wherein average roughnesses of said first through third semiconductor layers are less than 10 Å.

9. The semiconductor structure according to claim 3, wherein average roughnesses of said first through third semiconductor layers are less than 10 Å.

10. A method of fabricating a semiconductor structure used for manufacturing bipolar transistors, said method comprising:
depositing a first layer on a substrate, wherein said first layer includes a first semiconductor layer of a first conductivity type;
depositing a second layer on said first layer, wherein said second layer includes a second semiconductor layer of a second conductivity type;
depositing a third layer on said second layer, wherein said third layer includes a third semiconductor layer of said first conductivity type;
packing said substrate into a box with said third layer covered with nothing; and
sealing said box.

11. The method according to claim 10, wherein said first semiconductor layer mainly consists of silicon, and
wherein said second semiconductor layer mainly consists of silicon and germanium, and
wherein said third semiconductor layer mainly consists of silicon.

12. The method according to claim 11, wherein said second semiconductor layer has a germanium concentration of more than 2.5 atomic percent.

13. A method of fabricating and selling a transistor, comprising:
purchasing a semiconductor structure;
manufacturing a bipolar transistor in said semiconductor structure; and
shipping said bipolar transistor, wherein said semiconductor structure consists of:
a first layer covering said substrate, said first layer comprising a first semiconductor layer of a first conductivity type,
a second layer covering said first layer, said second layer comprising a second semiconductor layer of a second conductivity type, and
a third layer covering said second layer, said third layer comprising a third semiconductor layer of said first conductivity type.

14. The method according to claim 13, wherein said first semiconductor layer mainly consists of silicon, and
wherein said second semiconductor layer mainly consists of silicon and germanium, and
wherein said third semiconductor layer mainly consists of silicon.

15. The method according to claim 14, wherein said second semiconductor layer has a germanium content of more than 2.5 atomic percent.

16. A method of fabricating a switching circuit, comprising:
purchasing a semiconductor structure;
manufacturing a bipolar transistor in said semiconductor structure; and
assembling said bipolar transistor into a switching circuit, wherein said semiconductor structure consists of:
a first layer covering said substrate, said first layer comprising a first semiconductor layer of a first conductivity type,
a second layer covering said first layer, said second layer comprising a second semiconductor layer of a second conductivity type, and
a third layer covering said second layer, said third layer comprising a third semiconductor layer of said first conductivity type.

17. The method according to claim 16, wherein said first semiconductor layer mainly consists of silicon, and
wherein said second semiconductor layer mainly consists of silicon and germanium, and
wherein said third semiconductor layer mainly consists of silicon.

18. The method according to claim 17, wherein said second semiconductor layer has a germanium content of more than 2.5 atomic percent.
